(19) United States
(12) Patent Application Publication
(10) Pub. No.: US 2023/0258555 A1
(43) Pub. Date: Aug. 17, 2023

(54) DETERIORATION ESTIMATE SYSTEM

(71) Applicant: DAIWA CAN COMPANY, Chiyoda-ku (JP)

(72) Inventors: Rie SATO, Sagamihara-shi (JP); Akira NAGASHIMA, Sagamihara-shi (JP); Kouichiro NAKAMURA, Sagamihara-shi (JP); Takashi KUSAYANAGI, Sagamihara-shi (JP); Sin OU, (US)

(73) Assignee: DAIWA CAN COMPANY, Chiyoda-ku (JP)

(21) Appl. No.: 18/003,887

(22) PCT Filed: May 24, 2021
(86) PCT No.: PCT/JP2021/019577

§ 371 Date: Dec. 29, 2022

(30) Foreign Application Priority Data
Jul. 1, 2020 (JP) 2020-113862

(51) Int. Cl. G01N 17/00; G06N 5/04

(52) U.S. Cl. CPC G01N 17/006; G06N 5/04

(57) ABSTRACT

To accurately estimate deterioration of a product in which contents is held in a metal container. The deterioration estimate system comprises: a predictive model 3 trained mechanically by a training data 1 collected through storage tests of the product; an inputter 5 transmitting data to estimate deterioration; and a transmitter 4 that transmitting a degree of the deterioration of the product computed by the predictive model 3 based on the data transmitted from the inputter 5. The training data 1 includes: data relating to the metal container of the product; data relating to the contents contained in the metal container; data relating to an environment where the product has been stored; and data relating to the degree of the deterioration of the product. The data transmitted from the inputter 5 includes: data relating to the container of a target product to estimate the degree of the deterioration, data relating to the contents of the target product; and data relating to an environment where the target product will be stored.

### TECHNICAL FIELD

The present invention relates to a system to estimate deterioration over time in a metal container of a product in which a predetermined contents is encapsulated, and more specifically, to a system configured to estimate e.g., corrosion (rust) utilizing a machine learning model.

### BACKGROUND ART

Metal containers made of steel or aluminum alloys, etc. are advantageous for beverage and food cans in terms of strength, durability or cost. However, metals would ionize and consequently leach into liquids such as water. In addition, most of fruit juices, lactic acid beverages, or prepared food products are acidic or alkaline. Therefore, in order to prevent direct contact between the contents and the metal, at least the inner surface of the metal container is coated by applying synthetic resin or attaching a film thereto. For this reason, the inner surface of the metal container will not be rusted or corroded so that deterioration of taste or flavor of the contents is prevented.

However, a contact between the contents and the material of the inner surface of the container may not be prevented completely and permanently, and corrosion (rust) of the inner surface of the container may occur sooner than expected depending on the coating material, composition of the contents, or thickness of the coating. Therefore, in the conventional art, storage tests of most of the products are conducted to measure corrosion (rust) of the metal of the inner surfaces. In the storage test, a test sample of an actual commodity is prepared and stored under a predetermined storage condition for several months or a several tens of months, and then opened to investigate and measure deterioration such as corrosion (rust).

Although safeness and reliability are required to be checked and ensured for the new products, the new products are released one after another in accordance with the needs of the market. That is, a development cycle of the new products is shorter than a required period of time for carrying out the storage tests, and hence the new products may not be released smoothly due to storage tests.

The enamel rate value method is known as a method for detecting defects in the inner surface coating of the metal containers. In this method, the defects are detected based on a current value flowing between the contents and the metal can across the inner surface coating by applying a voltage therebetween. An improved method and a device performing such method is disclosed in publications of Japanese Patent No. 2934164 and Japanese Patent No. 5830910.

In order to detect existence of defects and cracks in the coating and to predict the progress of corrosion of the metal sheet in a can to which an impact is applied, the device described in Japanese Patent No. 2934164 measures an electrical resistance of an inner surface coating after an impact is applied to the can. Japanese Patent No. 5830910 also describes a method for evaluating corrosion resistance by applying an electric current through an inner coating of a can. Specifically, a voltage of 50 mV to 200 mV is applied between a can trunk and an electrode immersed in the contents for 6 to 48 hours, and corrosion resistance is evaluated based on the order of the accumulated amount of the electric current flowing therebetween.

### SUMMARY OF INVENTION

### Technical Problem to be Solved by the Invention

Due to contact between the contents and the metal surface, the inner surface of the metal container is corroded, and a flavor and a taste of the contents are changed. Such deterioration of the products is considered to progress over time due to a variety of factors, including variations in the thickness of the inner coating depending on the properties of the contents and the production line of the containers, and damage of the coating due to deformation of the containers by external forces, or environmental conditions at the storage. According to the conventional storage tests, therefore, test samples of the commodity are stored under the environment similar to an actual environment of the storage location. However, the storage test takes long time as mentioned above. In addition, if the test results are unsatisfactory, the storage test of improved products will have to be conducted again. Thus, a long span of time is required to develop an improved product that will not deteriorate even after storing for a certain period of time. For this reason, it is rather difficult to timely release new products in accordance with the needs of the market.

The device described in Japanese Patent No. 2934164 can immediately detect defects in the inner surface coating of the metal container if a large current flows through the inner surface coating. According to the teachings of Japanese Patent No. 2934164, however, only the defects caused by a collision impact can be detected, and for example, corrosion of the inner surface progressing over time cannot be detected unless the product has been stored for a long period of time by conducting a storage test. In addition, extra operations and man-hours are required to prepare the test sample of the actual product.

According to the method described in Japanese Patent No. 5830910, as the device described in Japanese Patent No. 2934164, defects are detected by applying a voltage to the product. However, it takes 6 hours to 48 hours to obtain the order of the accumulated amount of the electric current, and hence the defects may not be detected rapidity. Moreover, extra operations and man-hours are also required to prepare the test sample of the actual product. In addition, it is also impossible to detect deterioration over time due to the storage environment and characteristics of the contents by the method described in Japanese Patent No. 5830910.

The present invention has been conceived noting the above-explained technical problems, and it is therefore an object of the present invention to provide a system configured to rapidly evaluate deterioration over time in a metal container of a product holding contents therein without manufacturing an actual product, so as to develop and manufacture the product promptly.

### Means for Solving the Problem

According to the present invention, there is provided a deterioration estimate system for a product in which contents is contained in a metal container. In order to achieve the above-explained objective, according to the present invention, the system is provided with: a predictive model that is trained by machine learning utilizing data obtained through storage tests of actual products as training data; an inputter that transmits data to estimate deterioration; and a transmitter that transmits a degree of the deterioration of the product computed by the predictive model based on the data transmitted from the inputter. Specifically, the training data includes: container data relating to the metal container of the actual product; contents data relating to the contents contained in the metal container of the actual product; environmental data relating to an environment where the actual product was stored; and deterioration data relating to the degree of the deterioration of the actual product. The data transmitted from the inputter includes: container data relating to the container of a target product to estimate the degree of the deterioration; contents data relating to the contents of the target product; and environmental data relating to an environment where the target product will be stored.

According to the present invention, the container may be made of a metal sheet having an inner coating. In addition, deterioration data relating to the degree of the deterioration transmitted from the transmitter and the deterioration data relating to the degree of the deterioration included in the training data may include at least any one of: a depth of corrosion on an inner surface of the metal sheet; an outline of the corrosion; a state of dispersion of the corrosion; and an amount of a metal elution to the contents.

According to the present invention, the deterioration estimate may further comprise an evaluator that evaluates the degree of the deterioration transmitted from the transmitter, and that sorts the degree of the deterioration into a plurality of grades.

According to the present invention, the container data may include any of: data relating to dimensions of each part of the container; data relating to material of the container; and data relating to an inner coating of the container. The contents data includes any one of: a type of the contents; an amount of the contents; and a pH value. The environmental data may include a temperature of the environment where the product is stored.

According to the present invention, the transmitter may be configured to transmit data while sorting the degree of the deterioration into a plurality of grades and labeling the sorted data.

According to the present invention, the evaluator may evaluate the degree of the deterioration based on the data sorted into the plurality of grades and labeled.

### ADVANTAGEOUS EFFECTS OF INVENTION

According to the present invention, in order to estimate a degree of deterioration of the actual product, the data relating to deterioration of the actual product over time is inputted to the predictive model trained by the training data collected by storing the actual product. The training data includes: the container data relating to the metal container of the actual product; the contents data relating to the contents; the environmental data relating to the environment where the actual product was stored; and the deterioration data relating to the degree of the deterioration of the actual product. The above-mentioned data items are correlated among one another with high accuracy. As to the target product to be tested to estimate a deterioration thereof, the container data relating to the container: the contents data relating to the contents of the target product; and the environmental data relating to the environment where the target product will be stored, are collected in advance. Those data items are stored in a database and transmitted from the inputter to the predictive model, and the computation result of a degree of deterioration is transmitted from the transmitter. According to the present invention, therefore, a degree of deterioration of the newly designed product may be estimated during the design phase based on the data relating to the above-mentioned data items. For this reason, the newly designed products may be developed and manufactured promptly without conducting a storage test for a long period of time.

That is, if the estimation result of the deterioration falls within an allowable range, a production line of the newly designed product may be started immediately. By contrast, if an estimated degree of deterioration is not tolerable, a design of the metal container and a property of the contents are partially altered, and a degree of deterioration is estimated again by the predictive model. As a result of repeating the estimation by the predictive model, the specifications of the product may be set in such a manner that the product will not deteriorate or a degree of deterioration thereof will fall within the allowable range. In this case, it is not necessary to manufacture the modified product and to conduct a storage test for the modified product, and hence the modified designed product may be developed and manufactured promptly. Thus, a degree of deterioration of the can container whose specifications are altered or the contents whose property is altered may be estimated easily. That is, the specifications of the metal container may be altered easily and the contents may be selected easily. For this reason, the newly designed products may be developed and manufactured promptly and easily.

According to the present invention, degrees of deteriorations estimated by the predictive model may be sorted into a plurality of grades to be transmitted from the transmitter. In addition, the estimation results thus sorted may be evaluated by the evaluator. Specifically, the sorted estimation results are labeled to indicate that the deterioration of the product is tolerable, that it is recommendable to conduct a storage test of the actual product, and that the design of the product have to be altered. Therefore, the degree of deterioration estimated by the predictive model may be utilized easily to design and develop new products.

### BRIEF DESCRIPTION OF DRAWINGS

FIG. 1 is a block diagram schematically showing one example of the embodiment of the present invention.

FIG. 2 is a partially omitted table showing one example of a database obtained by conducting a storage test.

FIG. 3 is a partially omitted table showing one example of grade labels according to the embodiment of the present invention.

FIG. 4 is a judging table according to the embodiment of the present invention.

### DESCRIPTION OF EMBODIMENT(S)

The present invention relates to a deterioration estimate system that estimates deterioration over time of a metal container of a product filled with contents, and more specifically, to a system that estimates a degree of deterioration of the metal container using an estimation model built by machine learning using a labeled data as a training data. The metal container includes a two-piece can and a three-piece can in which an opening end of a metal can trunk is closed by a metal lid, and a bottle-shaped can in which a cap is mounted on a neck portion formed on a bottle-shaped can trunk. Those metal containers are made of conventional metallic material e.g., steel and aluminum alloy. In addition, in order to prevent a direct contact between the contents and the metallic material, at least an inner surface of the metal container is covered with an inner coating. The inner surface of the metal container may be coated not only by applying synthetic resin coating to the inner surface of a metal sheet but also by applying a synthetic resin film to the inner surface of the metal sheet. Specifically, conventional synthetic resin material may be used to form the inner coating.

The contents held in the product includes beverage, prepared solid foods, powder or grains such as milk formula and so on.

The deterioration of the product having the metal container is caused mainly by corrosion (rust) of metallic material. In addition, elution of the metal is increased, and a flavor, a taste, and a color of the contents are changed by such corrosion of the metallic material. Nonetheless, the metal corrosion (rust) will not be caused in a product containing dry contents such as milk formula or protein powder. However, the dry contents may be deteriorated by a transformation thereof due to oxidation, and a flavor thereof may be changed by the synthetic resin forming the inner coating and the metallic material of the container.

The definition of the deterioration of the product discussed herein is a change of the product over time in given items measured by a conventional storage test, and in the storage test, the actual product is used as a test sample. In the storage test, the test samples are stored for a predetermined period of time under a predetermined environmental condition, and then opened to measure the change in each of the given items, e.g., corrosion (rust) of the metal container, and changes of a flavor, a taste, a color and so on of the contents.

Examples of the items (data) to identify the metal container of the test sample (product) include types of a can and a cap. Each type of can container has its own code name as e.g., a combination of alphabets and numbers in accordance with a shape, a material, and a size thereof. Likewise, each type of cap has its own code name as a combination of alphabets and numbers in accordance with a shape, a material, and a size thereof. Accordingly, data relating to the material and the size (dimensions of parts) of the metal container, data relating to the inner coating, and, data relating to the usage of bisphenol A etc. may be obtained based on the code names of the can container and the cap. More specifically, given that a paint coating is employed as the inner coating, the data relating to the inner coating includes a type of the paint or medium, a solid content, an amount of application, and a thickness. Whereas, given that a film is employed as the inner coating, the data relating to the inner coating includes a type and a thickness of the film, a structure of a layer(s), a degree of crystallinity, and a type and a thickness of a primary.

For example, a type of the contents is selected from a pre-packaged food, a non-prepackaged food, a sports drink, an alcoholic drink, a carbonated drink, a fruit juice, a dairy product, an energy drink with high calorific value, a food for specified health uses, a functional food, a quasi-drug, a solid, viscosity, vegetable, meat, seafood. In addition, chemical properties (data) of the contents for identifying the contents include data relating to Brix (a sugar content), an alcohol content, a gas volume, an air volume in the container, a color tone L representing a brightness, a color tone representing a redness or greenness, a color tone b representing yellowness or blueness, a color difference ΔE representing a linear distance between two colors within a color space, a metal elution, a total amount of the contents, an internal pressure, a pH value and so on.

Test items (data) for measuring a magnitude of change in the product include: a depth of corrosion (rust) on the inner surface of the metal container, a form of corrosion (rust) such as planner corrosion, spotty corrosion, cracked or blistered corrosion; a dispersion of corrosion (rust), and a flavor. The flavor is evaluated by a sensory test conducted by a tester.

Deterioration of the product is likely to be greatly influenced not only by a storage time of the product but also by a storage environment (conditions). Therefore, the items (data) to identify the storage environment (conditions) include e.g., a storage time, a storage temperature, a pressure, a brightness of lighting, an amount of ultraviolet rays, and a duration of vibration during delivery (transportation).

The deterioration estimate system according to the present invention is configured to perform machine-learning using data obtained through past storage tests conducted with actual products as training data to train a predictive model (a machine learning model), and to estimate a degree of deterioration using the predictive model. The storage tests may be conducted while changing a condition of the product. For example, the storage tests may be conducted while changing a posture of the product, e.g., while erecting and inverting the product, and while making a dent on the trunk portion.

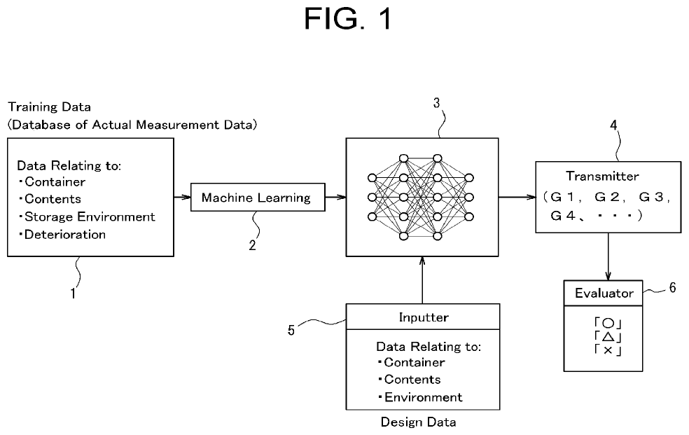

Turning now to FIG. 1, there is shown a brock diagram schematically showing one example of the deterioration estimate system according to the present invention. According to the example shown in FIG. 1, the training data 1 relates to the product tested in the actual storage test. The training data 1 includes: data relating to the metal container (container data); data relating to the contents (contents data); data relating to the storage environment (environmental data); data relating to a degree of deterioration measured by opening the product after a predetermined period of time (deterioration data). These data may be compiled into the database.

As previously explained, the container data includes a shape, dimensions, material of the metal container and material of the inner coating, etc., and the container data must include at least any one of the material and the dimensions of each part of the metal container. As also explained, the contents data includes: types of the contents such as a pre-packaged food, a non-prepackaged food, and a carbonated drink; and chemical properties such as a pH value, an alcohol content, and a color tone, and the contents data must include at least any one of a type, a quantity, and a pH value of the contents. The environmental data may include all of the foregoing data relating to the storage environment, but the environmental data must include at least temperature of the environment. The data relating to the degree of deterioration, which corresponds to ground truth, includes at least any one of a depth of corrosion (rust), a form of corrosion, and a flavor. Precision of the machine learning may be increased with an increase in an amount of collected data, but an enormous calculations are required to process those data. For this reason, it is preferable to process the data using a predetermined criteria for judgement. In a case of using neural network for machine learning, for example, the amount of the data may be reduced through convolutional layers and pooling layers.

The machine learning is the conventionally known method to perform computations by a neural network using the aforementioned training data as input data. By the machine learning, each parameter is tuned such that a degree of a computed deterioration is adjusted to an actual degree of deterioration measured by the storage test (i.e., a ground truth) as close as possible. The predictive model (machine learning model) 3 is built in consequence of tuning the parameters. The tuning may also be carried out sequentially.

For example, the predictive model 3 is a neurocomputer comprising an input layer, a single or multiple intermediate layer(s), and an output layer. Each parameter of the predictive model 3 is adjusted in such a manner as to reduce a difference between output values of given items and data relating to a degree of deterioration as the training data as much as possible. The computation results of the items by the predictive model 3 are transmitted from a transmitter 4 in the form of indexes as successive numerical values. The indexes may be sorted (or grouped or divided into grades) into plurality of data groups (or grades) by order, and the sored data groups (or grades) may be labeled to be transmitted.

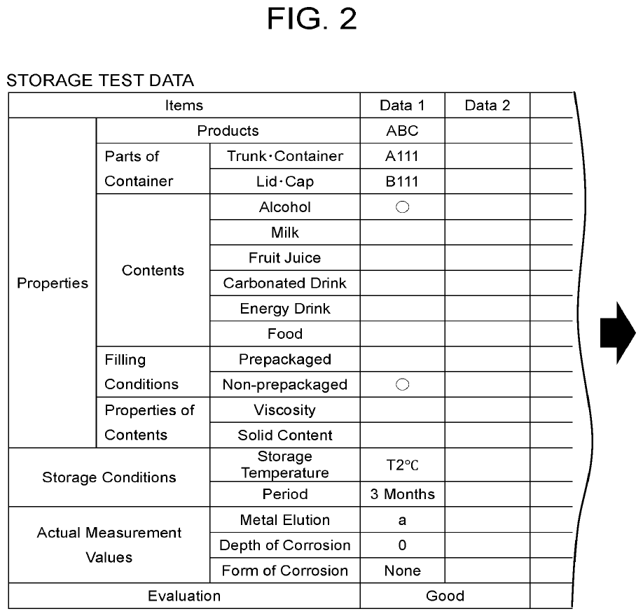

Turning to FIG. 2, there is shown a table showing one example of data (a storage test database) obtained by conducting the storage test. In FIG. 2, although only blanks in the column of “Data 1” are filled with data, blanks in the subsequent columns from “Data 2” are also filled with accumulated actual measurement data of same items as those of “Data 1” to be employed as training data.

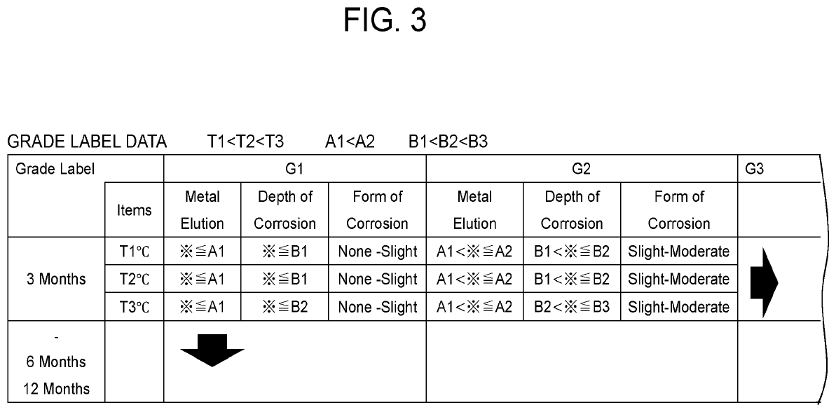

FIG. 3 shows one example of data (grade label data) as the sorted and labeled computation results transmitted from the transmitter 4. In the example shown therein, the index representing the degree of deterioration of the product is categorized into a metal elution, a depth of corrosion, and a form of corrosion. The form of corrosion is determined by visually confirming an amount, an outline, and a state (i.e., a form) of dispersion of the corrosion (rust). In the example shown in FIG. 3, a storage period is divided into three periods such as three months, six months, and twelve months, and a temperature is employed as the environmental data. The grade label data in each storage period is sorted in order from the lowest degree of deterioration as indicated as G1, G2, and G3, . . . The contents of each of the grade labels are shown in FIG. 3.

In order to estimate a degree of deterioration of a new product (designed product) over time without conducting a storage test, an inputter 5 transmits data (design data) relating to the designed product (a target product to estimate the degree of deterioration) to the predictive model 3, and the transmitter 4 transmits computation results. To this end, the data relating to the items included in the training data 1 used to build the predictive model 3 may be employed as the design data, and for example, the data shown in FIG. 2 may be employed as the design data. Actual values of the design data may not be always same as the training data 1, but the design data transmitted to the predictive model 3 would not be different significantly from the training data 1 which is also transmitted to the predictive model 3. For this reason, output values of the predictive model 3 should be similar to or same as the data included in the training data 1 indicating the degree of deterioration. Consequently, the grade label data (grade label) e.g., G1, G2 shown in FIG. 3 of each item (metal elution, depth of corrosion, form of corrosion etc.) will be transmitted to indicate the degree of deterioration of the product.

The computation results transmitted from the transmitter 4 are merely numeral values or labels, but the computation results indicate an estimated degree of deterioration. Therefore, based on the computation results, it is possible to estimate that a designed product will not deteriorate within a predetermined period of time, that the designed product is expected to deteriorate slightly, and that the designed product is expected to deteriorate severely to be defective, within a predetermined period of time. In addition, if the estimation fails due to ambiguous estimation results, it is also possible to determine a necessity to conduct a storage test again.

Such estimation may be made by a human estimator. However, if the number of items indicating the degree of deterioration is too large, this makes it difficult to evaluate the deterioration by the human evaluator. Consequently, the evaluation results would be varied, and the designed product (new product) would be handled improperly. For example, given that there are three items individually indicating a degree of deterioration and that four grade labels are applied to each of the items, the total number of combinations of the grade labels to determine an acceptance of the designed product will be sixty-four. In this case, it would be difficult to determine an acceptance of the designed product, necessity to alter a design of the designed product, and a necessity of the storage test. In addition, the evaluation result would be varied. In order to avoid such disadvantages, an evaluator 6 that can make an accurate evaluation may be employed.

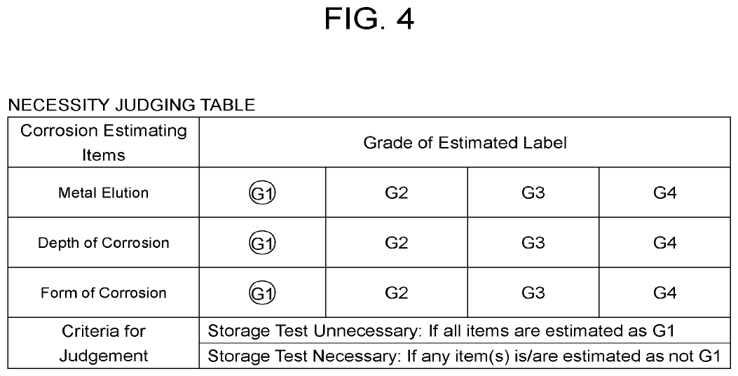

For example, the evaluator 6 judges a necessity of the storage test based on a combination of the grade labels with reference to a table shown in FIG. 4. In the example shown in FIG. 4, each of the three items for estimating a degree of deterioration is individually categorized into four grades, and the grade label data relating to each of the items transmitted from the transmitter 4 is surrounded by a circle “○” to determine a degree of deterioration. In the example shown in FIG. 4, all the three items for evaluating a degree of deterioration of the designed product are determined as the lowest grade (G1). In this case, therefore, the evaluator 6 evaluates that the designed product will not deteriorate to be a defective after a storage for a predetermined period of time under the expected environment. That is, the evaluator 6 determines that it is not necessary to conduct the storage test. For example, such determination result may be indicated visually by “○”. In this case, a production of the designed product may be started without conducting a storage test that requires a long period of time. The evaluator 6 may be configured not only to thus receive data from the transmitter 4 to perform evaluation, but also to be combined with the transmitter 4.

Whereas, in a case that any one of the three items for evaluating a degree of deterioration of the designed product is other than the lowest grade “G1”, it is necessary to conduct a storage test of the actual product for a predetermined period of time under the expected environment. In this case, such determination result may be indicated visually by L. Although not especially shown in FIG. 4, in a case that more than two of the three items for evaluating a degree of deterioration of the designed product are “G3”, or in a case that at least one of the three items for evaluating a degree of deterioration of the designed product is/are “G4”, it is possible to determine to alter a design of the metal container of the product or a property of the contents. In this case, such determination result may be indicated visually by X.

The degree of deterioration estimated by the estimate system as explained above may be utilized effectively and effectually to develop a new product. For this reason, it is possible to reduce the number of products requiring to conduct a storage test thereof which may take a long (period of) time. Consequently, lead times to develop new products may be shortened so that the new products may be released timely in response to needs of the market changing frequently in a short time. In other words, wasted time to conduct storage tests for products expected to be defected during the storage tests may be reduced. For this reason, designs of such products expected to be defected during the storage tests may be altered without conducting the storage test. Therefore, as described above, lead times to develop new products may be shortened so that the new products may be released timely in response to needs of the market changing frequently in a short time.

Here, the computation results of the predictive model 3 are merely estimations of a degree of deterioration, and do not guarantee that the product will not deteriorate 100 percent. Therefore, the inventors of the present invention validated accuracy of the predictive model built by themselves by a cross validation method, and found that an accuracy rate of the predictive model was 70% to 95%. In other words, the computation results of the predictive model contain at least 5% of error. Therefore, given that beverage or food is held in the product, the accuracy of the estimation result must be further improved. For example, the accuracy of the estimation result may be improved by setting a higher criterion for evaluation made by the evaluator 6 so that the estimate system according to the present invention may be employed to estimate a degree of deterioration of the product containing e.g., food. To this end, the higher criterion may be set by increasing the number of items for evaluating a degree of deterioration, dividing the grade label of each of the items more finely, or updating the parameters of the predictive model 3 by additional actual measurement data.

As described in the foregoing descriptions, the new products containing food or beverage have to be developed in short cycles to be released in response to a change in the needs of the market. In addition, chemical properties of the products vary widely. The estimate system according to the present invention is effective to accurately estimate a degree of deterioration of the product. Nonetheless, the estimate system according to the present invention should not be limited to evaluate the product containing food or beverage, and may also be employed to estimate a degree of deterioration of a metal container containing an industrial product.

1. A deterioration estimate system for a product in which contents are contained in a metal container, the system comprising:
a predictive model that is trained by machine learning utilizing data obtained through storage tests of actual products as training data;
an inputter that transmits data to estimate deterioration; and
a transmitter that transmits a degree of the deterioration of the product computed by the predictive model based on the data transmitted from the inputter,
wherein the training data includes
container data relating to the metal container of the actual product,
contents data relating to the contents contained in the metal container of the actual product,
environmental data relating to an environment where the actual product was stored, and
deterioration data relating to the degree of the deterioration of the actual product, and
the data transmitted from the inputter includes
container data relating to the container of a target product to estimate the degree of the deterioration,
contents data relating to the contents of the target product, and
environmental data relating to an environment where the target product will be stored.

2. The deterioration estimate system as claimed in claim 1,
wherein the container is made of a metal sheet having an inner coating, and
deterioration data relating to the degree of the deterioration transmitted from the transmitter and the deterioration data relating to the degree of the deterioration included in the training data include at least any one of: a depth of corrosion on an inner surface of the metal sheet; an outline of the corrosion; a state of dispersion of the corrosion; and an amount of a metal elution to the contents.

3. The deterioration estimate system as claimed in claim 1, further comprising an evaluator that evaluates the degree of the deterioration transmitted from the transmitter, and that sorts the degree of the deterioration into a plurality of grades.

4. The deterioration estimate system as claimed in claim 1,
wherein the container data includes any of: data relating to dimensions of each part of the container; data relating to material of the container; and data relating to an inner coating of the container,
the contents data includes any one of: a type of the contents; an amount of the contents; and a pH value, and
the environmental data includes a temperature of the environment where the product is stored.

5. The deterioration estimate system as claimed in claim 1, wherein the transmitter is configured to transmit data while sorting the degree of the deterioration into a plurality of grades and labeling the sorted data.

6. The deterioration estimate system as claimed in claim 5, wherein the evaluator evaluates the degree of the deterioration based on the data sorted into the plurality of grades and labeled.
